(19) United States
(12) Patent Application Publication
(10) Pub. No.: US 2012/0013220 A1
(43) Pub. Date: Jan. 19, 2012

(54) PIEZOELECTRIC ACTUATOR DRIVE UNIT

(75) Inventors: Takahiro KAWATA, Higashimurayama (JP); Ryusuke Sahara, Mitaka (JP); Satoshi Ueno, Akiruno (JP)

(73) Assignee: HITACHI, LTD.

(21) Appl. No.: 13/182,846

(22) Filed: Jul. 14, 2011

(30) Foreign Application Priority Data
Jul. 15, 2010 (JP) 2010-160206

(51) Int. Cl. H01L 41/09

(52) U.S. Cl. 310/317

(57) ABSTRACT

Disclosed is a piezoelectric actuator drive unit that includes a piezoelectric actuator drive amplifier and a piezoelectric actuator drive unit power supply. Combinations of high and low signal levels of a first control signal, which controls the supply voltage and amplifier bias voltage of the piezoelectric actuator drive amplifier, and a second control signal, which controls the driving force of the piezoelectric actuator drive amplifier, are associated with a haptic feedback function, a receiver function for generating an audio output, and a speaker function for generating music or the like. Thus, the piezoelectric actuator drive unit, which vibrates a piezoelectric actuator, is adapted to the haptic feedback function, the receiver function, and the speaker function, and can optimize its power and drive amplifier characteristics.

### CLAIM OF PRIORITY

The present application claims priority from Japanese patent application JP 2010-160206 filed on Jul. 15, 2010, the content of which is hereby incorporated by reference into this application.

### FIELD OF THE INVENTION

The present invention relates to a piezoelectric actuator drive unit having a haptic feedback function, a receiver function for generating an audio output, and a speaker function for generating music.

### BACKGROUND OF THE INVENTION

As disclosed in Japanese Unexamined Patent Application Publication No. 2009-169612, touch panel input devices use a piezoelectric actuator that provides a haptic feedback to give the sense of an operation by imparting vibration to a fingertip of a user who operates the device. In addition, the touch panel input devices cause the piezoelectric actuator or a touch panel having the piezoelectric actuator to emit a sound.

As disclosed in Japanese Unexamined Patent Application Publication No. 2006-54693, mobile terminals such as mobile telephones offer sound generation functions such as a receiver function for generating an audio output and a speaker function for generating music and the like.

### SUMMARY OF THE INVENTION

As described above, there are three piezoelectric actuator vibration functions: a haptic feedback function (hereinafter referred to as the haptic function), a receiver function, and a speaker function. The haptic function provides a haptic feedback by imparting vibration to give the sense of an operation. The receiver function generates an audio output. The speaker function generates music and the like. These three functions differ in the characteristics (frequency band, output voltage amplitude, driving force, and distortion characteristic) required of a drive amplifier for a piezoelectric actuator drive unit. Therefore, it is necessary to provide a piezoelectric actuator drive unit capable of vibrating a piezoelectric actuator that supports the aforementioned three functions.

In Japanese Unexamined Patent Application Publication No. 2009-169612, however, a drive amplifier characteristics changeover capability supporting the above three functions is not taken into consideration.

In Japanese Unexamined Patent Application Publication No. 2006-54693, the haptic function is not considered as a capability for vibrating a piezoelectric actuator. Further, as regards the receiver function for generating an audio output and the speaker function for generating music and the like, the driving force changeover of a drive amplifier is not taken into consideration.

The present invention has been made in view of the above circumstances, and provides a piezoelectric actuator drive unit that optimizes its power and drive amplifier characteristics In consideration of the three piezoelectric actuator vibration functions, namely, the haptic function, the receiver function for generating an audio output, and the speaker function for generating music and the like.

A representative aspect of the present invention disclosed in this document is outlined below.

According to the representative aspect of the present invention, a piezoelectric actuator drive unit for vibrating a piezoelectric actuator includes a single-differential converter, a high-voltage amplifier, a power supply, and a current source section. The single-differential converter includes an amplifier bias voltage generator for controlling an amplifier bias voltage in accordance with an input first control signal, converts a single input signal to a differential output, and outputs a differential output signal. The high-voltage amplifier amplifies the differential output signal. The power supply controls a supply voltage of the high-voltage amplifier in accordance with the input first control signal. The current source section controls an amplifier bias current amount of the high-voltage amplifier in accordance with an input second control signal. A haptic feedback function, a receiver function for generating an audio output, and a speaker function for generating music are incorporated as piezoelectric actuator vibration functions. Combinations of a first signal level and a second signal level of both the first and second control signals are associated with the haptic feedback function, the receiver function, and the speaker function to control the amplifier bias voltage, the supply voltage of the high-voltage amplifier, and the amplifier bias current amount of the high-voltage amplifier.

The present invention makes it possible to optimize the power and drive amplifier characteristics of the piezoelectric actuator drive unit in consideration of the haptic function, the receiver function, and the speaker function.

### BRIEF DESCRIPTION OF THE DRAWINGS

Embodiments of the present invention will be described in detail based on the following figures, in which:

FIG. 1 is a schematic block diagram illustrating the configuration of a system according to a first embodiment of the present invention;

FIG. 2 is a block diagram illustrating the configuration of a piezoelectric actuator drive unit according to the first embodiment;

FIG. 3 is a block diagram illustrating the configuration of a single-differential converter according to the first embodiment;

FIG. 4 is a block diagram illustrating the configuration of a high-voltage amplifier according to the first embodiment;

FIG. 5 is a block diagram illustrating the configuration of a piezoelectric actuator drive unit power supply according to the first embodiment;

FIG. 6 is a schematic diagram illustrating operating waveforms of the piezoelectric actuator drive unit power supply according to the first embodiment;

FIG. 7 is a schematic diagram illustrating operating waveforms of the piezoelectric actuator drive unit power supply according to the first embodiment;

FIG. 8 is a block diagram illustrating the configuration of a gate controller according to a second embodiment of the present invention; and

FIG. 9 is a schematic diagram illustrating operating waveforms of the piezoelectric actuator drive unit power supply according to the second embodiment.

### DETAILED DESCRIPTION OF THE PREFERRED EMBODIMENTS

Embodiments of the present invention will now be described with reference to the accompanying drawings.

### First Embodiment

A first embodiment of the present invention is described below with reference to a case where one piezoelectric actuator drive unit drives one piezoelectric actuator.

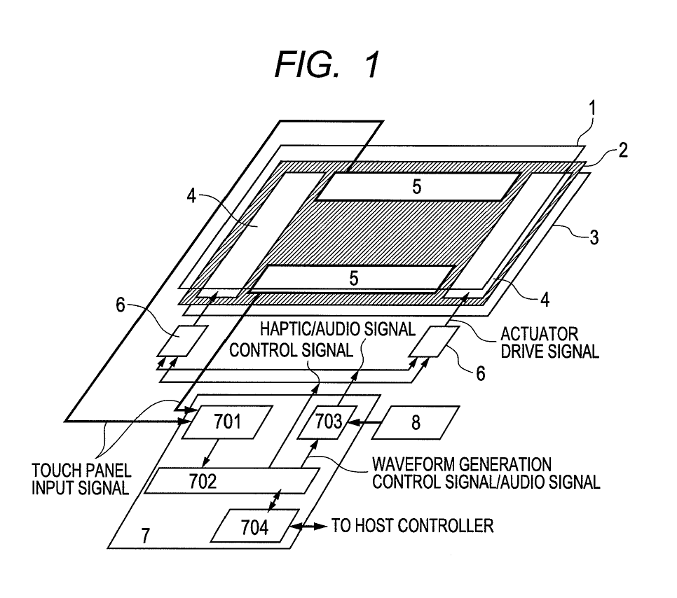

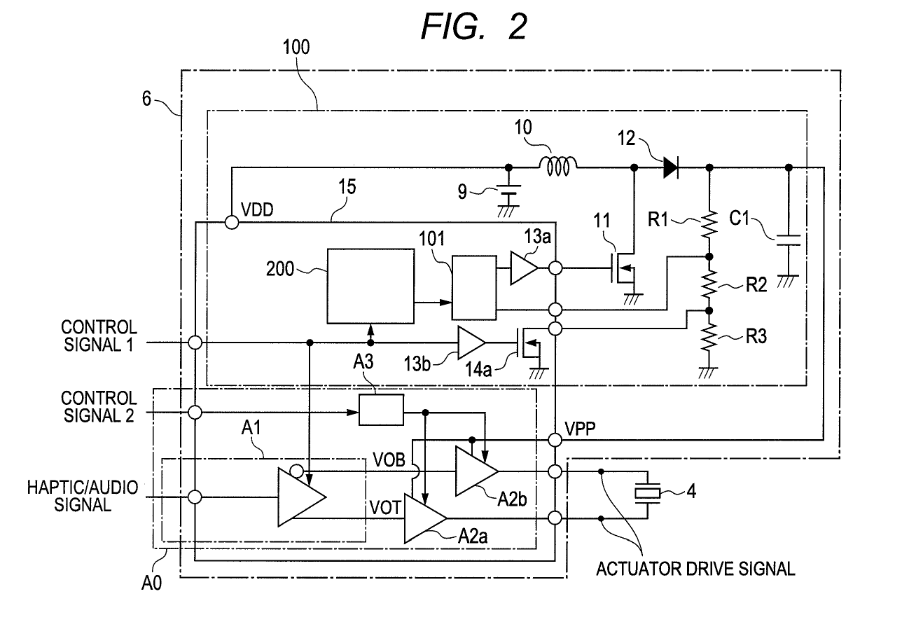

FIG. 1 is a schematic block diagram illustrating the configuration of a system according to the first embodiment. FIG. 2 is a block diagram illustrating the configuration of a piezoelectric actuator drive unit according to the first embodiment, which is shown in FIG. 1.

Referring to FIG. 1, a piezoelectric actuator 4 is mounted on a panel that includes a touch panel 1, a vibration panel 2, and a liquid-crystal panel 3. A piezoelectric actuator drive unit 6 is provided for each piezoelectric actuator. A touch panel sensor 5 disposed on the touch panel generates a touch panel input signal from the touch panel and transmits the generated touch panel input signal to a controller 7. A touch panel circuit 701 of the controller 7 processes the touch panel input signal to detect a position with which a user's fingertip is brought into contact when the surface of the touch panel is touched, generates a signal indicative of the detected position, and transmits the generated signal to a control circuit 702.

The control circuit 702, which includes, for instance, an MCU (microcontroller unit), outputs a waveform generation control signal or an audio signal to a waveform generation circuit 703 in order to generate a predefined haptic vibration, sound, or audio signal in accordance with the contact position. It is assumed that the acoustic signal is input from a host controller to the control circuit 702 through a communication interface 704. The waveform generation circuit 703 references waveform data in a data storage 8 in accordance with the waveform generation control signal and acoustic signal, and outputs a haptic/acoustic signal to the piezoelectric actuator drive unit 6.

The control circuit 702 operates so that a predefined control signal is generated in the piezoelectric actuator drive unit 6 to exercise the haptic function, the receiver function, or the speaker function in accordance with the contact position of the touch panel. Alternatively, the controller 7 may transmit a touch panel input signal to the host controller so that a control signal from the host controller to the piezoelectric actuator drive unit 6 can be received through the communication interface 704 and the control circuit 702.

While the system configuration is as described above, the configuration of the piezoelectric actuator drive unit 6 will be described below with reference to FIG. 2. FIG. 2 shows a case where a piezoelectric actuator drive IC 15 is used as a part of the piezoelectric actuator drive unit 6. Alternatively, the piezoelectric actuator drive unit 6 may be wholly formed by a piezoelectric actuator drive IC or SiP (System in Package) or other similar module.

The piezoelectric actuator drive unit 6 mainly includes a piezoelectric actuator drive amplifier A0 and a piezoelectric actuator drive unit power supply 100.

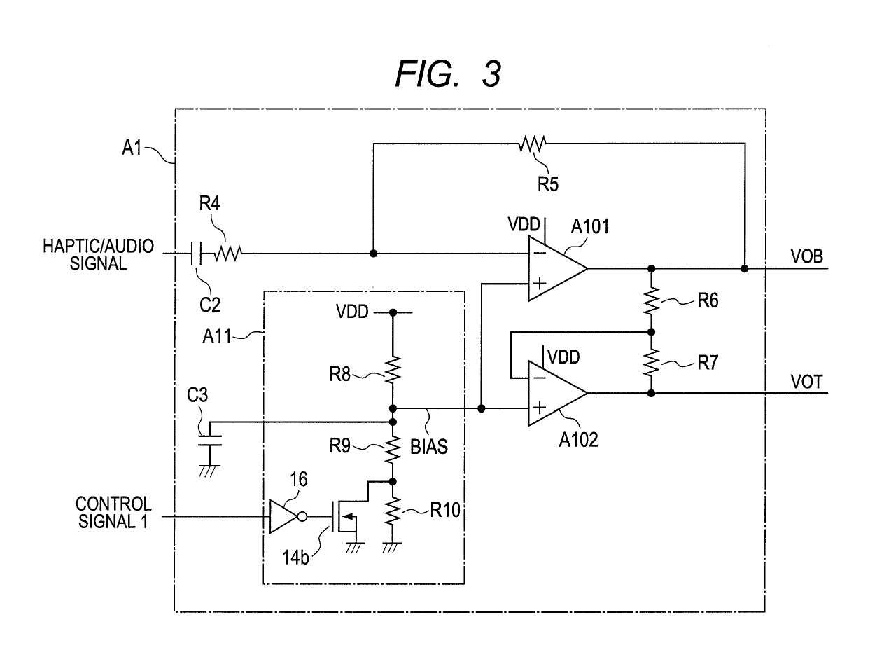

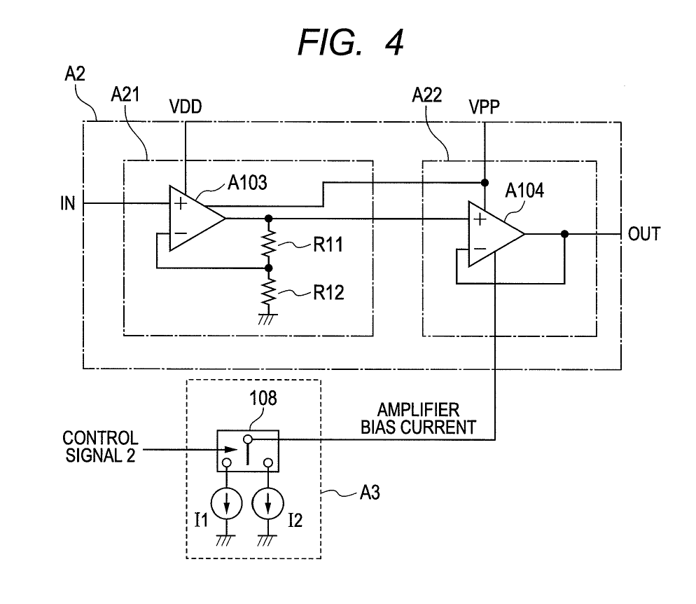

The piezoelectric actuator drive amplifier A0 mainly includes a single-differential converter A1 and high-voltage amplifiers A2 (A2a, A2b). The piezoelectric actuator drive amplifier A0 can amplify the haptic/acoustic signal, which is an amplifier input signal, and drive the piezoelectric actuator 4 by using a BTL output so that the amplitude can be increased substantially twofold by applying an opposite-phase signal across the terminals of the piezoelectric actuator 4. The configuration and operation of the piezoelectric actuator drive amplifier A0 will now be described with reference to FIGS. 3 and 4.

As shown in FIG. 3, the single-differential converter Al has a circuit that includes amplifiers A101, A102 and resistive elements R4-R7. This circuit converts the haptic/acoustic signal, which is a single input signal, to a differential output and differentially outputs it as single-differential conversion circuit outputs VOT, VOB. In this instance, the VOT is a signal that is in phase with the input signal, whereas the VOB is an inverted signal. The input signal is input into the single-differential converter through a high-pass filter that includes the resistive element R4 and a capacitive element C2. The high-pass filter cuts a DC component of the input signal and eliminates low-frequency noise.

An amplifier bias voltage generator All adjusts the VOT and VOB output signals in accordance with the level (high or low) of control signal 1. When control signal 1 is at a certain level (high or low), an amplifier bias voltage BIAS of the VOT/VOB output signal is set to be high. When control signal 1 is at the other level, the amplifier bias voltage BIAS of the VOT/VOB output signal is set to be low.

Referring to FIG. 3, the amplifier bias voltage BIAS is generated by voltage-dividing a voltage from a low-voltage power supply VDD by using resistors R8, R9, R10. An NMOS 14b is turned on/off in accordance with the level (high or low) of control signal 1 to vary the voltage division ratio, thereby changing the output voltage level of the amplifier bias voltage BIAS. A capacitor C3 is provided as a bypass capacitor for the amplifier bias voltage BIAS.

When control signal 1 at the high level is input into the NMOS 14b through an inverter 16, the amplifier bias voltage BIAS is VDD×(R9+R10)/(R8+R9+R10). When, on the other hand, control signal 1 is at the low level, the amplifier bias voltage BIAS is VDD×R9/(R8+R9).

When, for instance, VDD=5 V, R 8=200 kΩ, R9=8 kΩ, and R10=125 kΩ, the amplifier bias voltage BIAS is approximately 2.0 V if control signal 1 is at the high level or approximately 0.2 V if control signal 1 is at the low level.

The high-voltage amplifiers A2 have a circuit that includes a gain amplifier A21 and a voltage follower A22 as shown in FIG. 4, inputs the VOT and VOB signals output from the single-differential converter A1, and amplifies the input signals. The high-voltage amplifiers A2a, A2b shown in FIG. 2 have the same configuration as the high-voltage amplifiers A2 shown in FIG. 4. The gain amplifier A21 uses an amplifier A103 and resistive elements R11, R12 to amplify a voltage amplitude by a factor of (R11+R12)/R12. A high-voltage power supply VPP is adjusted in accordance with the level (high or low) of the control signal. As described later, the present embodiment increases the VPP voltage when control signal 1 is at the high level and decreases the VPP voltage when control signal 1 is at the low level. Further, when the amplifier bias voltage generated by the amplifier bias voltage generator All shown in FIG. 3 is properly set, control can be exercised so that a maximum output voltage amplitude of the piezoelectric actuator drive amplifier A0 increases when control signal 1 is at the high level and decreases when control signal 1 is at the low level.

If, for instance, the gain of the gain amplifier A21 is set to be 50 while control signal 1 for the aforementioned amplifier bias voltage BIAS is at the high level, the amplifier output of the high-voltage amplifiers A2 is such that the voltage amplitude can be centered around approximately 100 V. Therefore, when the high-voltage power supply VPP is set at a voltage of 200 V or higher, the output of the high-voltage amplifiers A2 is such that an amplitude of ±100 V is obtained around 100 V. As the BTL output shown in FIG. 2, a peak-to-peak voltage amplitude of up to 400 V can be obtained.

Meanwhile, if the gain of the gain amplifier A21 is set to be 50 while control signal 1 is at the low level, the amplifier output of the high-voltage amplifiers A2 is such that the voltage amplitude can be centered around approximately 10 V. Therefore, when the high-voltage power supply VPP is set at a voltage of 20 V or higher, the output of the high-voltage amplifiers A2 is such that an amplitude of ±10 V is obtained around 10 V. As the BTL output, a peak-to-peak voltage amplitude of up to 20 V can be obtained.

As described above, the VPP voltage and the amplifier bias voltage are both increased accordingly when control signal 1 is at the high level, and both decreased accordingly when control signal 1 is at the low level. In other words, the maximum output voltage amplitude of the drive amplifier is increased accordingly when control signal 1 is at the high level, and decreased accordingly when control signal 1 is at the low level. This makes it possible to optimize the power and drive amplifier characteristics of the piezoelectric actuator drive unit in consideration of the haptic function, the receiver function, and the speaker function.

More specifically, as regards the haptic function, the amplitude of the piezoelectric actuator needs to be increased so that a user's fingertip feels adequate vibration when the panel surface is touched. Thus, the present embodiment associates the high signal level of control signal 1 with the haptic function, raises the VPP power supply voltage, and changes the amplifier bias voltage, thereby providing control to increase the maximum output voltage amplitude of the piezoelectric actuator drive amplifier.

As regards the speaker function, which requires that an adequate sound pressure be generated from the panel, the amplitude of the piezoelectric actuator needs to be increased. Thus, the present embodiment associates the high signal level of control signal 1 with the speaker function, raises the VPP power supply voltage, and changes the amplifier bias voltage, thereby providing control to increase the maximum output voltage amplitude of the piezoelectric actuator drive amplifier.

On the other hand, the receiver function, which is used to listen to a sound with a user's ear positioned close to the panel, does not require a substantial sound pressure unlike the speaker function. Therefore, the receiver function requires a smaller piezoelectric actuator amplitude than the other functions. Thus, the present embodiment associates the low signal level of control signal 1 with the speaker function, lowers the VPP power supply voltage, and changes the amplifier bias voltage, thereby providing control to decrease the maximum output voltage amplitude of the piezoelectric actuator drive amplifier. Decreasing the output voltage amplitude of the drive amplifier makes it possible to provide power reduction and optimize the power of the piezoelectric actuator drive unit. In the present embodiment, it is assumed that the maximum output voltage amplitude is increased in response to the high level of control signal 1 and decreased in response to the low level of control signal 1. However, it is obvious that the maximum output voltage amplitude may alternatively be decreased in response to the high level of control signal 1 and increased in response to the low level of control signal 1.

An amplifier bias current input into the voltage follower A22 is generated by a current source section A3. The amount of amplifier bias current is controlled in accordance with the level (high or low) of control signal 2. As shown in FIG. 4, the current source section A3 includes current sources I1, I2, which differ in the amount of current b, and uses a selector 108 to change the amount of current in accordance with the level (high or low) of control signal 2.

If, for instance, an amplifier A104 is a class AB amplifier, the driving force of the high-voltage amplifiers A2 increases with an increase in the amount of amplifier bias current. This makes it possible to increase cut-off frequency and improve the amplifier distortion characteristic. However, current consumption and power consumption increase.

When a haptic signal for the haptic function is to be driven, an amplifier frequency band of up to several hundred hertz will suffice due to the relationship to the haptic feeling of a fingertip. When, on the other hand, an acoustic signal for the receiver function or the speaker function is to be driven, an amplifier frequency band of at least several kilohertz is required because the audible range of frequencies is from 20 Hz to 20 kHz.

Consequently, sound quality improvement is achieved, for instance, by associating the low level of control signal 2 with the receiver function and speaker function, increasing the amount of amplifier bias current, increasing the driving force of the high-voltage amplifiers A2, and increasing the high-frequency of a cut-off frequency range.

Meanwhile, power reduction is achieved by associating the high level of control signal 2 with the haptic function, decreasing the amount of amplifier bias current, decreasing the driving force of the high-voltage amplifiers A2, and decreasing the high-frequency of the cut-off frequency range.

The above makes it possible to optimize the power of the piezoelectric actuator drive unit and the band and distortion characteristic of the drive amplifier.

In the present embodiment, it is assumed that the amount of amplifier bias current is increased in response to the low level of control signal 2 and decreased in response to the high level of control signal 2. However, it is obvious that the amount of amplifier bias current may alternatively be increased in response to the high level of control signal 2 and decreased in response to the low level of control signal 2.

The piezoelectric actuator drive unit power supply 100 generates the VPP voltage with a booster DC-DC converter that includes a battery 9, an inductor element 10, a MOSFET element 11, a diode element 12, and a capacitive element C1 as shown in FIG. 2. The VPP voltage is resistive voltage divided by resistive elements R1, R2, R3 and fed back to a gate controller 101. A gate of the MOSFET element 11 is switched by a switching oscillation circuit 200, the gate controller 101, and a driver 13a.

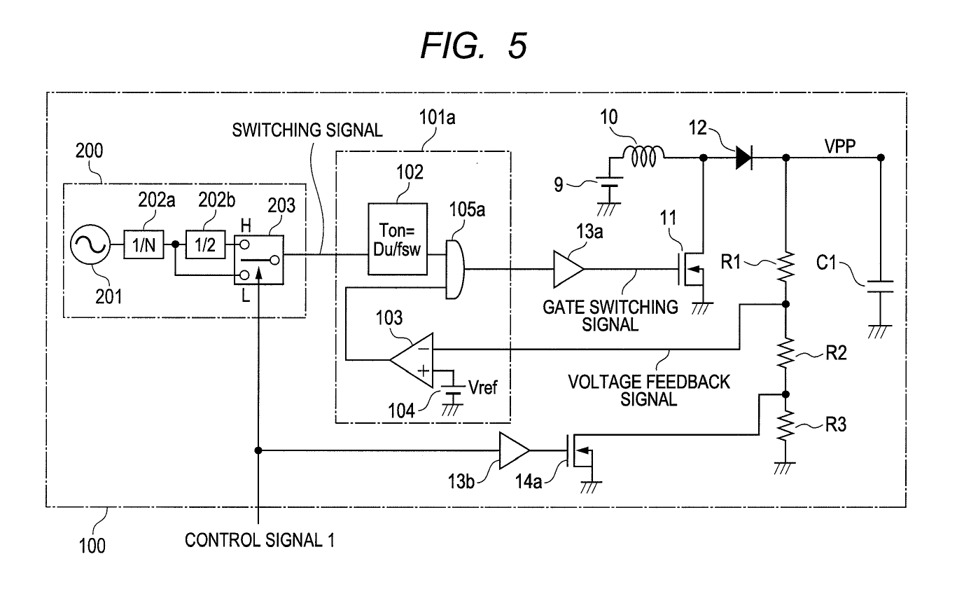

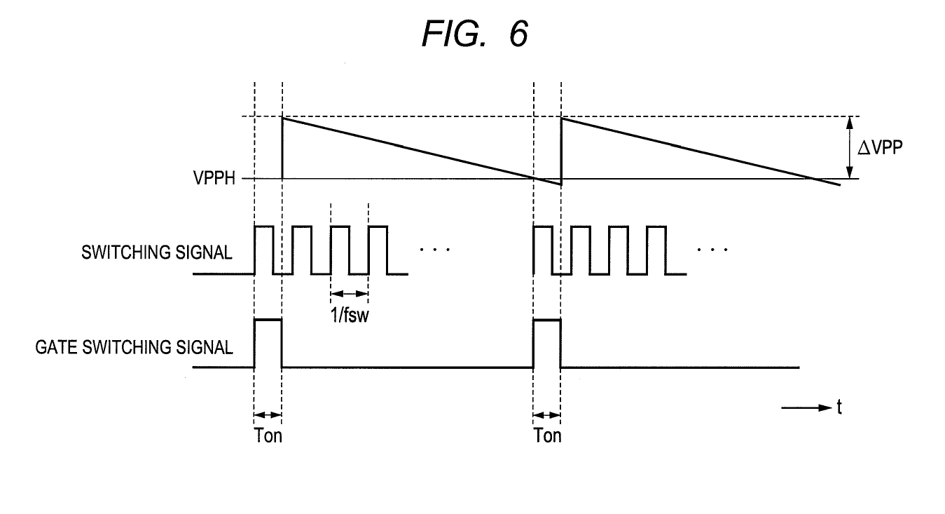

The configuration and operation of the piezoelectric actuator drive unit power supply 100 will now be described with reference to FIGS. 5 and 6. First of all, the fact that the VPP voltage can be varied in accordance with the level (high or low) of control signal 1 will be described below.

FIG. 5 shows a booster DC-DC converter control scheme. Here, as a control system can be configured by a comparator 103 alone even when a later-described boosting ratio is great, a nonlinear control method is employed because it excels in controls system stability. When control signal 1 is at the high level, a gate of an NMOS 14a is turned on through the driver 13b. A voltage feedback signal input into the comparator 103 of a gate controller 101a is VPP×R2/(R1+R2). When a reference voltage Vref 104 is set for the other input of the comparator 103, VPP×R2/(R1+R2)=Vref. Therefore, when the VPP voltage prevailing when control signal 1 is at the high level is VPPH, VPPH=(R1+R2)/R2×Vref.

Similarly, when control signal 1 is at the low level, the gate of the NMOS 14a is turned OFF. Therefore, when the resulting VPP voltage is VPPL, VPPL=(R1+R2+R3)/(R2+R3)×Vref.

If, for instance, R1=500 kΩ, R2=5 kΩ, R3=50 kΩ, and Vref=2 V, VPPH=202 V when control signal 1 is at the high level, and VPPL=approximately 20.2 V when control signal 1 is at the low level.

As described above, the VPP voltage can be controlled in accordance with the level (high or low) of control signal 1. The present embodiment exercises control in such a manner that the VPP voltage increases at the high level and decreases at the low level.

A method of improving the distortion characteristic when the level of control signal 1 is changed from high to low will now be described.

The ratio of an output voltage change to an amplifier output voltage amplitude affects the distortion characteristic. More specifically, the degree of distortion characteristic deterioration increases with an increase in the ratio of the output voltage change to the amplifier output voltage amplitude. As mentioned earlier, when the piezoelectric actuator drive unit switches from the haptic function or speaker function t the receiver function, the level of control signal 1 changes from high to low. In this instance, the output voltage change remains the same no matter whether the level of control signal 1 is high or low. Therefore, the problem is that the distortion characteristic deteriorates accordingly as the output voltage amplitude is relatively small when control signal 1 is at the low level.

In view of the above circumstances, the present embodiment controls a switching frequency in accordance with the level of control signal 1. More specifically, the present embodiment increases the frequency when the level of control signal 1 changes from high to low. This makes it possible to reduce the output voltage change, thereby improving the distortion characteristic. Details are given below with reference to FIGS. 5 to 7.

In the switching oscillation circuit 200, a signal generated by an oscillation circuit 201 is frequency-divided by a frequency divider 202b to generate a switching signal having a frequency of fsw.

When the VPP voltage level falls below the aforementioned VPPH voltage level or VPPL voltage level, an output signal of the comparator 103 is at the high level. Thus, an output signal of a gate on-time generation circuit 102 is output from the gate controller 101a through an AND circuit 105a. In this instance, a gate switching signal is placed at the high level through the driver 13a to turn on the gate of the MOSFET element 11.

Time Ton at which the gate switching signal goes high as shown in FIG. 6 when control signal 1 is at the high level is generated by the gate on-time generation circuit 102 in accordance with the switching signal having a frequency of fsw. Further, a constant Du is used in such a manner that Ton=Du/fsw. The constant Du is hereinafter referred to as the duty ratio for the switching signal.

If, in this instance, the voltage of the battery 9 included in the booster DC-DC converter is VDD and the inductance of the inductor element 10 is L, the maximum current flowing in the inductor element (hereinafter referred to as the Ip) is Ip=VDD/L×Ton=(VDD×Du)/(L×fsw).

In the present embodiment, the VPP voltage is VPPH when control signal 1 is at the high level, as described earlier. Further, the battery voltage VDD is approximately 3.5 V in consideration of the fact that a lithium-ion battery is commonly used to generate the battery voltage VDD in mobile phones and other mobile terminals. Therefore, when, for instance, VPPH=202 V, the boosting ratio is as great as 202 V/3.5 V=58. Consequently, the value IP needs to be great to achieve boosting.

When, on the other hand, control signal 1 is at the low level, the VPP voltage is approximately VPPL. If, for instance, VPPL=20.2 V, the boosting ratio is 20.2 V/3.5 V=5.8. When the equivalent series resistance ESR of the capacitive element C1, which is used as indicated in FIG. 1 to provide output smoothing capacitance of the boosting DC-DC converter, is a, a ripple ΔVPP of the VPP voltage can be expressed as ΔVPP=Ip×α. More specifically, even when the level of control signal 1 changes from high to low, the value Ip remains unchanged. It means that the ripple of the VPP voltage also remains unchanged.

Further, when the power supply rejection ratio PSRR of the amplifier relative to the high-voltage power supply VPP is β, an amplifier output voltage change of αVPP∴β occurs. When control signal 1 is at the low level, the ratio of the output voltage change to the output voltage amplitude increases by an amount by which the amplifier output voltage amplitude is made smaller than at the high level. This will adversely affect the distortion characteristic of an amplifier output of the piezoelectric actuator drive amplifier A0.

To avoid the above problem, a selector 203 selects the switching signal supplied through the frequency divider 202b when control signal 1 is at the high level, as shown in FIG. 5. In this instance, the frequency is set at fsw.

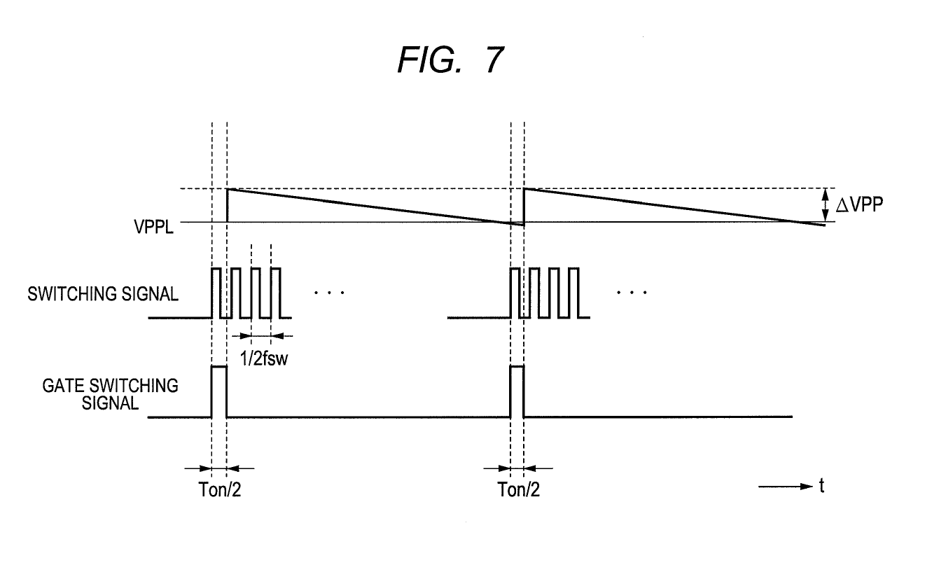

When, on the other hand, control signal 1 is at the low level, the selector 203 selects the switching signal that is not supplied through the frequency divider 202b. As a result, the switching signal is set to a frequency of 2 fsw in the example shown, for instance, in FIG. 5. As indicated by the above relational expression of the value Ip, the value Ip is decreased to half as compared to a case where control signal 1 is at the high level. Further, the ripple of the VPP voltage and the output voltage change are both reduced to half as indicated in FIG. 7. Thus, the distortion characteristic of the amplifier output can be improved. As described above, increasing the frequency fsw of the switching signal for the booster DC-DC converter when the level of control signal 1 changes from high to low makes it possible to reduce the ripple of the VPP voltage, thereby improving the distortion characteristic of the amplifier output.

### Second Embodiment

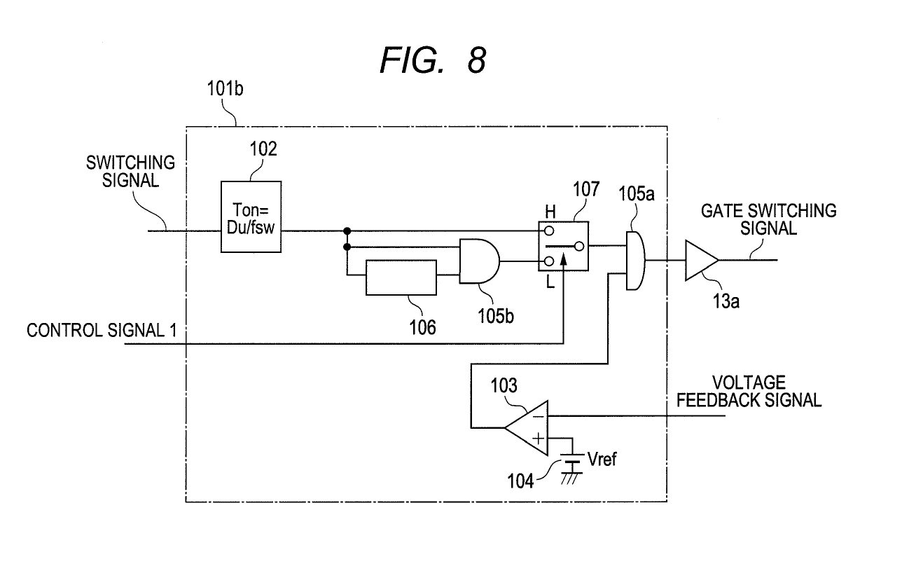

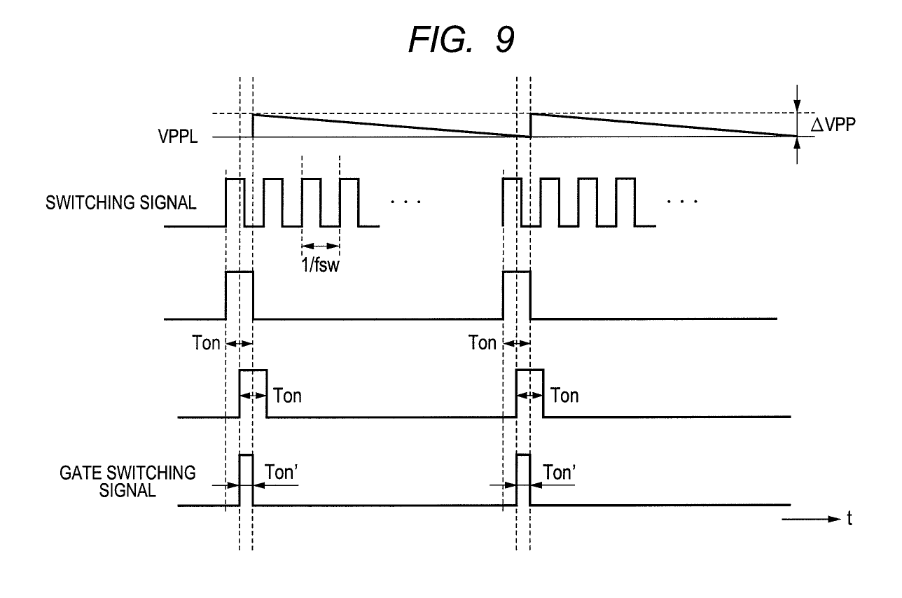

A second embodiment of the present invention is described below with reference to FIGS. 8 and 9 to explain about another method of reducing the ripple of the VPP voltage for the purpose of improving the distortion characteristic of the amplifier output.

As shown in FIG. 8, the second embodiment includes a delay circuit 106, an AND circuit 105b, and a selector 107, and controls the duty ratio in accordance with the level of control signal 1. More specifically, the second embodiment is characterized in that the duty ratio is decreased when the level of control signal 1 changes from high to low. This makes it possible to shorten the on time of the gate switching signal and reduce the ripple of the VPP voltage, thereby improving the distortion characteristic of the amplifier output.

As shown in FIG. 8, a gate controller 101b controls an output of the gate on-time generation circuit 102 with the selector 107 so that a signal supplied through the delay circuit 106 and the AND circuit 105b is input into the AND circuit 105a when the level of control signal 1 changes from high to low.

In the above instance, the on time Ton′ of the gate switching signal is obtained when a signal generated in the gate on-time generation circuit 102, which indicates that Ton=Du/fsw, is ANDed with a signal obtained by delaying the generated signal, as shown in FIG. 9. Thus, the gate on-time can be reduced. When the duty ratio in the present embodiment is Du′, Ton′=Du′/fsw<Ton=Du/fsw. In other words, the present embodiment provides control to reduce the duty ratio Du for the switching signal while the first embodiment controls the frequency fsw. This makes it possible to reduce the ripple of the VPP voltage, thereby improving the distortion characteristic of the amplifier output.

As described above, in the piezoelectric actuator drive unit 6, which includes the piezoelectric actuator drive amplifier A0 and the piezoelectric actuator drive unit power supply 100, the high and low levels of control signal 1, which controls the supply voltage VPP and amplifier bias voltage of the piezoelectric actuator drive amplifier A0, and of control signal 2, which controls the driving force of the piezoelectric actuator drive amplifier A0, are variously combined and adapted to the haptic function, receiver function, and speaker function. This enables the piezoelectric actuator drive unit to optimize the power and drive amplifier characteristics in consideration of the above three functions.

In the foregoing embodiments, it is assumed that the battery 9 is used as a source of supplying the low-voltage power VDD. Alternatively, however, the low-voltage power VDD may be supplied from the battery 9 through a regulator or the like.

FIG. 1 indicates that the piezoelectric actuator drive unit 6, the controller 7, and the data storage 8 are separate units. However, an alternative is to configure the system by integrating the piezoelectric actuator drive unit 6 and the controller 7 into a single unit. Another alternative is to configure the system by integrating the piezoelectric actuator drive unit 6, the controller 7, and the data storage 8 into a single unit . In such an instance, control signal 1 and control signal 2 need not be provided separately as input signals for the piezoelectric actuator drive unit 6. The controller 7 may use a serial communication method or the like to receive control signals equivalent to control signal 1 and control signal 2. This will reduce the required mounting space.

In the first embodiment, it is assumed that one piezoelectric actuator drive unit drives one piezoelectric actuator. However, an alternative is to configure the system by allowing one piezoelectric actuator drive unit to drive plural piezoelectric actuators. Another alternative is to configure the system by allowing plural piezoelectric actuator drive units to drive one piezoelectric actuator.

While the present invention has been described in conjunction with presently preferred embodiments of the invention, persons of skill in the art will appreciate that the invention is not limited to the preferred embodiments, and that various modifications and appropriate combinations of the foregoing preferred embodiments may occur insofar as they are within the scope of the appended claims or the equivalents thereof.

What is claimed is:

1. A piezoelectric actuator drive unit for vibrating a piezoelectric actuator, the piezoelectric actuator drive unit comprising:
a single-differential converter that includes an amplifier bias voltage generator for controlling an amplifier bias voltage in accordance with an input first control signal, converts a single input signal to a differential output, and outputs a differential output signal;
a high-voltage amplifier that amplifies the differential output signal;
a power supply that controls a supply voltage of the high-voltage amplifier in accordance with the input first control signal; and
a current source section that controls an amplifier bias current amount of the high-voltage amplifier in accordance with an input second control signal;
wherein a haptic feedback function, a receiver function for generating an audio output, and a speaker function for generating music are incorporated as functions that vibrate the piezoelectric actuator; and
wherein combinations of a first signal level and a second signal level of both the first and second control signals are associated with the haptic feedback function, the receiver function, and the speaker function to control the amplifier bias voltage, the supply voltage of the high-voltage amplifier, and the amplifier bias current amount of the high-voltage amplifier.

2. The piezoelectric actuator drive unit according to claim 1, wherein the second control signal controls a driving force of the high-voltage amplifier.

3. The piezoelectric actuator drive unit according to claim 1, wherein the haptic feedback function provides control to increase the amplifier bias voltage and the supply voltage of the high-voltage amplifier when the first control signal is at the first signal level, and provides control to decrease the amplifier bias current amount of the high-voltage amplifier when the second control signal is at the first signal level.

4. The piezoelectric actuator drive unit according to claim 1, wherein the receiver function provides control to decrease the amplifier bias voltage and the supply voltage of the high-voltage amplifier when the first control signal is at the second signal level, and provides control to increase the amplifier bias current amount of the high-voltage amplifier when the second control signal is at the second signal level.

5. The piezoelectric actuator drive unit according to claim 1, wherein the speaker function provides control to increase the amplifier bias voltage and the supply voltage of the high-voltage amplifier when the first control signal is at the first signal level, and provides control to increase the amplifier bias current amount of the high-voltage amplifier when the second control signal is at the second signal level.

6. The piezoelectric actuator drive unit according to claim 1, further comprising:
an oscillation circuit;
wherein the power supply includes a booster DC-DC converter; and
wherein the oscillation circuit controls the frequency of a switching signal for the booster DC-DC converter in accordance with the level of the first control signal.

7. The piezoelectric actuator drive unit according to claim 6, wherein the oscillation circuit increases the frequency when the first control signal changes from the first signal level to the second signal level.

8. The piezoelectric actuator drive unit according to claim 1, further comprising:
a gate controller;
wherein the power supply includes a booster DC-DC converter; and
wherein the gate controller controls the duty ratio of a switching signal for the booster DC-DC converter in accordance with the level of the first control signal.

9. The piezoelectric actuator drive unit according to claim 8, wherein the gate controller decreases the duty ratio when the first control signal changes from the first signal level to the second signal level.
